(19) United States
(12) Patent Application Publication
(10) Pub. No.: US 2007/0117423 A1
(43) Pub. Date: May 24, 2007

(54) Camera module using printed circuit board with step portion

(75) Inventors: Gab Yong Kim, Suwon (KR); Seung Ju Lee, Namyangju (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon-si (KR)

(21) Appl. No.: 11/598,699

(22) Filed: Nov. 14, 2006

(30) Foreign Application Priority Data
Nov. 23, 2005 (KR) 10-2005-0112158

(51) Int. Cl. H05K 1/00

(52) U.S. Cl. 439/83

(57) ABSTRACT

Provided is a camera module using a PCB with a step portion. The camera module includes a PCB, a housing, and a lens barrel. The PCB includes a substrate main body, a plurality of pads, and a step portion. The substrate main body is formed of a stacked structure with the shape of a rectangular plate. The pads is formed on both sides of the top of the substrate main body and is electrically connected through wires to an image sensor mounted on a central portion of the top of the substrate main body. The step portion is formed at the peripheral edges of the pads. The housing has a bottom peripheral portion that is closely attached to the step portion of the PCB. The lens barrel is installed vertically in an upper region of the housing. Accordingly, it is possible to enhance the quality of image taken by the image sensor. In addition, the contact area between the housing and the PCB is increased to make it possible to enhance the assembly reliability of the camera module.

### CROSS-REFERENCE TO RELATED APPLICATIONS

This application claims the benefit of Korean Patent Application No. 2005-112158 filed with the Korea Industrial Property Office on Nov. 23, 2005, the disclosure of which is incorporated herein by reference.

### BACKGROUND OF THE INVENTION

1. Field of the Invention

The present invention relates to a camera module using a printed circuit board (PCB) with a step portion. In the camera module, a step portion is formed along the edge of the PCB and the bottom portion of a housing is inserted and attached into the step portion. Accordingly, it is possible to prevent external light from penetrating through the adhesion portion between the housing and the PCB. Accordingly, it is possible to enhance the quality of image taken by the image sensor. In addition, the contact area between the housing and the PCB is increased, which makes it possible to enhance the assembly reliability of the camera module.

2. Description of the Related Art

With the recent development of mobile terminals such as portable phones and Personal Digital Assistants (PDAs), the mobile terminals provide a phone call function and are used as multi-convergence devices. The most representative of the multi-convergence devices is a camera module. The resolution of the camera module changes from 300,000 pixels (VGA) to 700,000 pixels. Moreover, the camera module provides various additional functions, such as auto-focusing (AF) and optical zoom.

In addition, as a portable phone decreases in thickness and size, a camera module installed in the portable phone is miniaturized. Contrary to the miniaturization of the camera module, the number of pixels of the camera module increases with the performance enhancement of the camera module, which necessitates the image sensor to relatively increase in size. What is therefore required is a module design that makes it possible to reduce the thickness of a component of the camera module and to minimize the assembly space in the camera module.

In the case of a conventional camera module mounted on a PCB, the bottom portion of a housing of the camera module is adhered and fixed to the edge of the PCB by adhesive such as epoxy. However, the epoxy may be insufficiently coated between the PCB and the housing. In addition, the adhesive performance of the epoxy may degrade with the lapse of a long time. In this case, the whole or portion of the camera module may be separated due to an external vibration or impact. These problems will now be described in detail with reference to FIGS. 1 to 3.

FIG. 1 is a sectional view of a conventional PCB 1, and FIG. 2 is a plan view of the conventional PCB 1.

Referring to FIGS. 1 and 2, the conventional PCB 1 includes a top base layer 2 and a bottom base layer 3 that are bonded together using a bonding sheet 4. The top base layer 2 includes an insulating layer 2a and a copper foil layer 2b that are bonded together by thermocompression bonding. Likewise, the bottom base layer 3 includes an insulating layer 3a and a copper foil layer 3b that are bonded together by thermocompression bonding.

Each of the insulating layers 2a and 3a is laminated with a dry film for forming circuit patterns, a photolithography process is performed to form the circuit patterns, and a cover layer 5 is attached onto the resulting structure.

Pattern portions 6 connected to the circuit patterns are formed at given positions inside each side edge thereof, so that they are electrically connected by wire bonding or bump contact to a chip-type image sensor 7 that is mounted onto the PCB 1.

FIG. 3 is a sectional view of a conventional camera module fabricated using the conventional PCB 1.

Referring to FIG. 3, the edge of the PCB 1 is coated with an adhesive 12. The bottom peripheral region of a housing 11 of a camera module 10 is adhered closely onto the plane of the adhesive coated portion, and the adhesive 12 is hardened to fix the adhesion portion.

In the conventional camera module, the whole or portion of the bottom of the housing 11 may be separated from the PCB 1 due to degradation of the adhesive performance of the adhesive 12. The miniaturization of the camera module leads to a decrease in the thickness of the housing. This reduces the contact area, which worsens the above problem. Also, external light may penetrate through the separation gap of the two members.

In addition, because the adhesive 12 is generally formed of transparent epoxy resin, external light may penetrate through the adhesion portion of the hardened epoxy resin.

### SUMMARY OF THE INVENTION

An advantage of the present invention is that it provides a camera module using a PCB with a step portion, in which a step portion is formed along the edge of the PCB and the bottom portion of a housing is inserted and attached into the step portion. Accordingly, it is possible to prevent external light from penetrating through the adhesion portion between the housing and the PCB. Accordingly, it is possible to enhance the quality of image taken by the image sensor. In addition, the contact area between the housing and the PCB is increased, which makes it possible to enhance the assembly reliability of the camera module.

The present invention also provides a camera module comprising: a PCB on which an image sensor is mounted and along the edge of which a step portion is formed; a housing in which an IR filter is installed and a bottom peripheral portion of which is closely attached to the step portion of the PCB; and a lens barrel installed vertically in an upper portion of the housing and including a plurality of stacked lenses therein.

Additional aspect and advantages of the present general inventive concept will be set forth in part in the description which follows and, in part, will be obvious from the description, or may be learned by practice of the general inventive concept.

According to an aspect of the invention, the PCB includes: a base film; a copper foil layer formed of copper foils stacked on both sides of the base film; a plating layer formed on the copper foil layer; and a cover layer attached onto the plating layer by thermal adhesion and including circuit patterns formed by photolithography. At this point, the edge of the uppermost layer of the PCB is removed along the edge thereof, thereby forming the step portion

According to another aspect of the invention, the step portion is formed along the edge of the PCB with the shape of a plate, the top surface of the step portion is coated with an adhesive such as epoxy, and the bottom portion of the housing is closely attached onto the step portion coated with the adhesive.

According to a further aspect of the invention, the step portion is formed to have a width equal to the thickness of the bottom peripheral portion of the housing.

According to a still further aspect of the invention, the forming of the step portion includes: forming a PI reinforcement plate (polyimide) on the uppermost layer of the PCB; and removing a portion where the PI reinforcement plate is not stacked.

According to a still further aspect of the invention, the forming of the step portion includes: reducing the area of the uppermost layer to the width of the step portion, stacking the reduced uppermost layer, and exposing the copper foil layer during a PSR process.

According to a still further aspect of the invention, the forming of the step portion may include etching the copper foil exposed along the edge of the PCB simultaneously with the process of etching the copper foil layer to form the circuit patterns.

According to a still further aspect of the present invention, a hotbar process using a thermocompression bonding technique is performed to attach the camera module onto the PCB. The bottom peripheral portion of the housing is closely attached to the step portion with the adhesive interposed therebetween. Accordingly, the camera module can be electrically connected to the PCB.

According to a still further aspect of the invention, the bottom peripheral portion of the housing is mounted on the step portion with an epoxy adhesive coated on the step portion, and the adhesive is hardened to attach and fix the housing vertically on the PCB.

In the camera module according to the present invention, the step portion is formed by performing an etching process to remove the edge of the PCB (i.e., a portion on which the bottom peripheral portion of the housing is mounted). Alternatively, the step portion is formed by forming the PI reinforcement plate on the image sensor-mounting portion except the edge portion such that the edge portion is lower in height. The bottom peripheral portion of the housing with the IR filter is mounted into the step portion with the adhesive interposed therebetween. Accordingly, a light penetration can be prevented by the step portion. In addition, the contact area between the housing and the PCB is expanded, which makes it possible to the reliability of a camera module product.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a sectional view of a conventional PCB, and FIG. 2 is a plan view of the conventional PCB;

FIG. 2 is a plan view of the conventional PCB;

FIG. 3 is a sectional view of a conventional camera module fabricated using the conventional PCB;

FIG. 4 is a sectional view of a PCB according to an embodiment of the present invention;

FIG. 5 is a perspective view of the PCB according to an embodiment of the present invention; and

FIG. 6 is a sectional view of a camera module fabricated using the PCB according to an embodiment of the present invention.

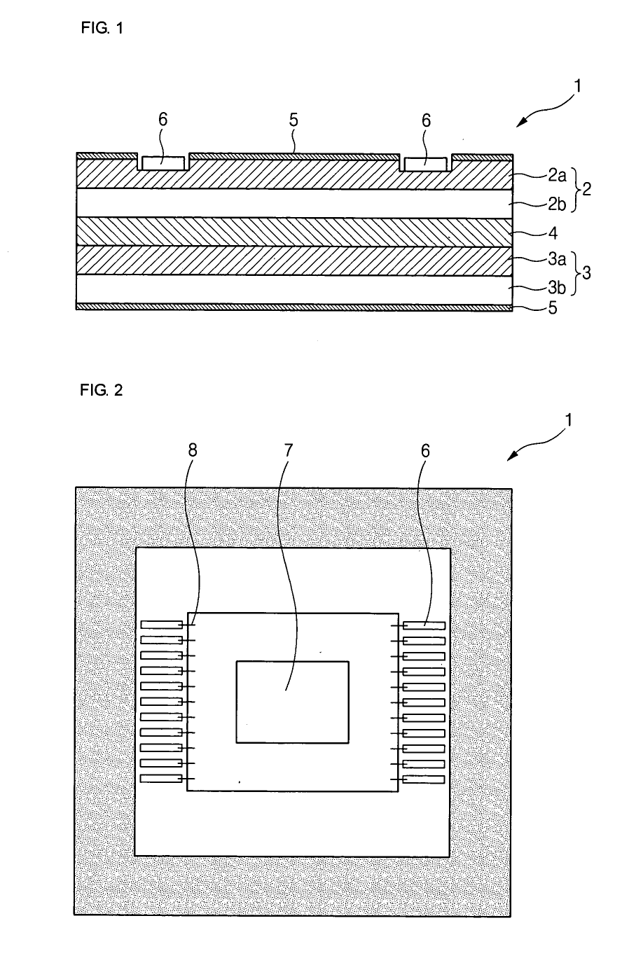

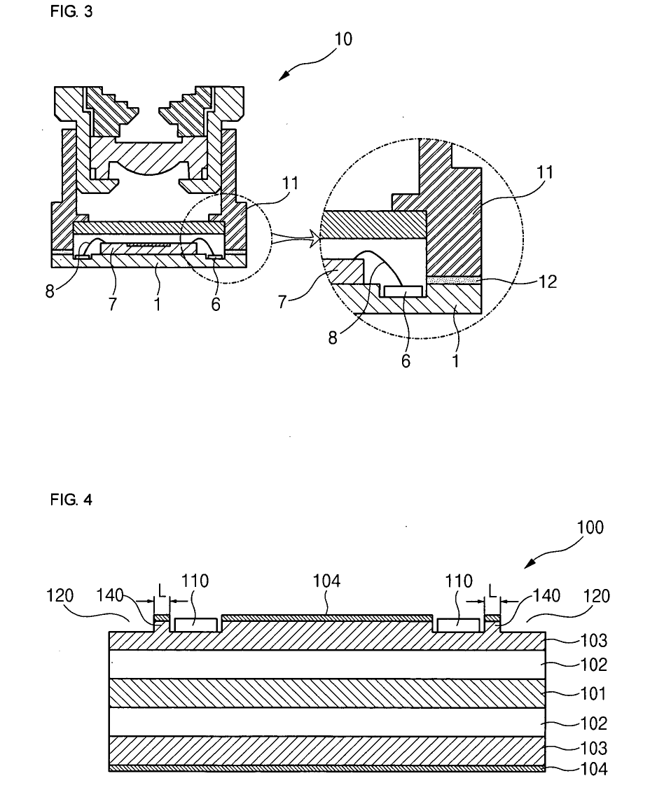

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, preferred embodiments of the present invention will be described in detail with reference to the accompanying drawings.

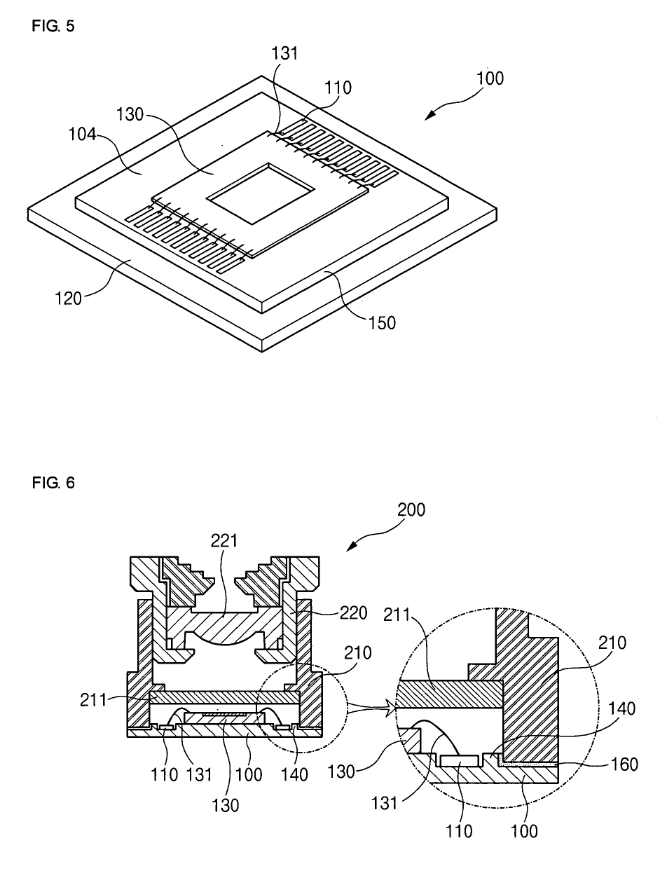

FIG. 4 is a sectional view of a PCB 100 according to an embodiment of the present invention, and FIG. 5 is a perspective view of the PCB 100 according to an embodiment of the present invention.

Referring to FIGS. 4 and 5, the PCB 100 includes a substrate main body 150 that has the shape of a rectangular plate. A plurality of pads 110 are formed on the substrate main body 150. An image sensor 130 is mounted on the central region of the substrate main body 150 in such a way that it is electrically connected to the pads 110. A step portion 120 is formed along the peripheral edge of the image sensor 130.

That is, the PCB 100 is fabricated in the shape of a chip-on-board (COB) package such that the image sensor 130 on the top center portion of the substrate main body 150 are electrically connected by a plurality of wires 131 to the pads 110 provided on the PCB 100.

The step portion 120 may be formed through various processes during the fabrication of the PCB 100. The step portion 120 is formed in the uniform width and thickness along the top edge of the retangular PCB 100.

A process of fabricating the substrate main body 150 and a process of forming the step portion 120 will now be described with reference to FIGS. 4 and 5.

Referring to FIGS. 4 and 5, the substrate main body 150 includes: a base film 101; copper foil layers 102 deposited respectively on the top and bottom surfaces of the base film 101; plating layers 103 formed respectively on the copper foil layers 102; and a cover layer 104 attached onto the top plating layer 103 by thermal adhesion. Circuit patterns are formed at the cover layer 104.

The base film 101 is formed of polyimide. The copper foil layer 102 formed on each of the top and bottom surfaces of the base film 101 is formed to include a plurality of stacked copper foils each having a thickness of about 8-70 μm. The plating layer 103 is formed on the top of the copper foil layer 102 by electro-copper plating (ECP). Thereafter, the plating layer 103 is polished and planarized.

The top of the plating layer 103 is laminated with a photoresist dry film. Thereafter, the copper foil layer 102 laminated with the photoresist dry film is exposed using an exposer device, thereby exposing necessary patterns.

In this way, a developer is coated to develop the exposed copper foil layer 103, and an etching process is performed to form necessary patterns. Thereafter, a thermal adhesion process using a press is performed to adhere the cover layer 104 onto the patterned PCB 100, thereby competing fabrication of the PCB 100.

The step portion 120 is formed on the edge of the PCB 100 such that it has a width equal to the width of a bottom peripheral region of a housing attached thereonto and has such a height that a portion of the bottom peripheral region of the housing can be inserted thereinto.

Methods of forming the step portion 120 on the substrate main body 150 will now be described in detail.

In the first method, a PI reinforcement plate is formed of polyimide on the uppermost layer of the substrate main body 150, and the image sensor 130 is mounted onto the PI reinforcement plate.

At this point, the PI reinforcement plate, which is cut off to a size that is smaller than the area of the uppermost layer by the width of the step portion, is stacked on the uppermost layer. Accordingly, the step portion 120 is formed outside of the PI reinforcement plate to a height equal to the thickness of the PI reinforcement plate.

In the second method, because the substrate main body 150 is configured to include a plurality of films and copper foil layers that are stacked, a portion of the edge of a resist layer forming a photo solder resist (PSR) layer on the uppermost layer of the substrate main body 150 is removed to expose the copper foil layer 102 formed thereunder and simultaneously to form the step portion 120 corresponding to the removed portion.

In the third method, the copper foil of the outermost region of the copper foil layer 102 between the layers of the substrate main body 150 is forcibly removed to form the step portion 120.

As described above, the circuit patterns are formed on the PCB 100, the top of the plating layer 103 is laminated with the dry film, the necessary patterns are exposed, and the exposed copper foil are developed. Thereafter, an etching process is performed to etch the outermost copper foil, thereby forming the step portion 120 along the edge of the substrate main body 150.

When the copper foil layer 102 is constructed to include four copper foils 102 each having a thickness of 25 μm, the step portion 120 is formed to a thickness of about 0.1 mm along the edge of the PCB 100.

As described above, the pads 110 are formed inside the step portion 120 such that they are electrically connected through the wires 131 to the image sensor 130. Accordingly, a protruding portion 140 is formed outside the pads 110 to a height equal to the height of the step portion 120. As a result, an adhesive 160 coated on the step portion 120 is prevented from flowing toward the pads 110.

Preferably, the protruding portion 140 is formed to a width L of about 20 μm.

According to the present invention, a lens unit including a housing is closely attached onto the PCB with the step portion, thereby forming a camera module. This process will now be described in detail with reference to FIG. 6.

FIG. 6 is a sectional view of a camera module 200 fabricated using the PCB 100 according to an embodiment of the present invention.

Referring to FIG. 6, the camera module 200 includes the PCB 100 with the shape of a plate. The step portion 120 is formed along the periphery region of the PCB 100 in four direction. The bottom peripheral region of a housing 210 is closely attached to the step portion 120 with the adhesive 160 interposed therebetween.

An image sensor 130 is disposed in the housing 210, and an IR filer 211 is adhered and fixed on the image sensor 130. A lens barrel 220 with a plurality of stacked lenses 221 is inserted and installed through a top opening of the housing 210.

The housing 210 is mounted on the PCB 100. The bottom peripheral portion of the housing 210 is inserted into the step portion 120 to the height of the step portion 120, and the adhesive 160 is injected therein with the housing 210 inserted. Accordingly, the bottom peripheral region of the housing 210 is closesly attached onto the bottom surface of the step portion 120.

At this point, it is preferable that the step portion 120 is formed to a width equal to the thickness of the bottom peripheral region of the housing 210.

According to the camera module of the invention as described above, the bottom portion of the housing is inserted and attached into the step portion formed in the PCB. Accordingly, it is possible to prevent external light from penetrating through the adhesion portion between the housing and the PCB. Consequently, it is possible to enhance the quality of image taken by the image sensor.

In addition, the contact area between the housing and the PCB is increased, which makes it possible to enhance the assembly reliability of the camera module.

Furthermore, the mounting position of the bottom portion of the housing on the PCB can be easily determined and the housing and the PCB can be conveniently assembled using a hotbar process. Accordingly, it is possible to enhance the production of camera module products.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A camera module comprising:
a printed circuit board (PCB) including:
a substrate main body formed of a stacked structure with the shape of a rectangular plate;
a plurality of pads formed on both sides of the top of the substrate main body and electrically connected through wires to an image sensor mounted on a central portion of the top of the substrate main body; and
a step portion formed at the peripheral edges of the pads;
a housing with a bottom peripheral portion that is closely attached to the step portion of the PCB; and
a lens barrel installed vertically in an upper portion of the housing.

2. The camera module according to claim 1,
wherein the step portion is formed to have a width equal to the thickness of the bottom peripheral portion of the housing.

3. The camera module according to claim 1,
wherein the step portion is formed by stacking an PI reinforcement plate on the uppermost layer of the substrate main body.

4. The camera module according to claim 3,
wherein the PI reinforcement plate is formed of polyimide.

5. The camera module according to claim 3,
wherein the PI reinforcement plate, which is cut off to a size that is smaller than the uppermost layer of the substrate main body by the width of the step portion, is stacked on the uppermost layer.

6. The camera module according to claim 1,
wherein the step portion is formed by removing an edge portion of a resist layer forming a photo solder resist layer on the uppermost layer of the substrate main body.

7. The camera module according to claim 1,
wherein the step portion is formed by removing a copper foil of the outermost region of copper foil layers disposed between layers of the substrate main body.

8. The camera module according to claim 7,
wherein the removing of the copper foil of the outermost region is performed simultaneously with an etching process for forming circuit patterns on the substrate main body.

9. The camera module according to claim 1,
further comprising a protruding portion formed inside the step portion to the height of the step portion.

10. The camera module according to claim 9,
wherein the protruding portion is formed to have a width of 20 μm.
